(19) United States
(12) Patent Application Publication
(10) Pub. No.: US 2019/0379310 A1
(43) Pub. Date: Dec. 12, 2019

(54) MOTOR DRIVING CIRCUIT

(71) Applicant: ANPEC ELECTRONICS CORPORATION, HSINCHU CITY (TW)

(72) Inventors: CHIA-TAI YANG, TAINAN CITY (TW); KUN-MIN CHEN, HSINCHU CITY (TW)

(21) Appl. No.: 16/126,856

(22) Filed: Sep. 10, 2018

(30) Foreign Application Priority Data
Jun. 6, 2018 (TW) 107119475

(51) Int. Cl. H02P 6/28; H02P 6/182; H03K 3/017; H03K 7/08

(52) U.S. Cl. CPC H02P 6/28; H02P 6/182; G05B 11/28; H03K 7/08; H03K 3/017

(57) ABSTRACT

A motor driving circuit includes a driving-stage circuit, a system control circuit, a signal generation circuit and a plurality of zero-crossing detectors. The driving-stage circuit includes a plurality of inverters. The system control circuit provides a duty cycle signal. The signal generation circuit generates a plurality of pulse width modulation signals according to the duty cycle signal to control the turning on and the turning off of an upper-side transistor and a lower-side transistor of each inverter such that the driving current is provided to drive the motor. The zero-crossing detector detects a current flowing through a node between the upper-side transistor and the lower-side transistor of each inverter and accordingly generates a current sensing signal. The signal generation circuit adjusts the pulse width modulation signals according to the current sensing signals.

### CROSS-REFERENCE TO RELATED PATENT APPLICATION

This application claims the benefit of priority to Taiwan Patent Application No. 107119475, filed on Jun. 6, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a motor driving circuit, and more particularly to a motor driving circuit that can compensate an extension of the equivalent duty cycle of its driving-stage circuit, which is caused by the dead time of the motor driving circuit.

### BACKGROUND OF THE DISCLOSURE

In a motor driving circuit, a system control circuit is configured to generate a duty cycle signal PWM (usually, a pulse width modulation signal). A signal generation circuit is configured to generate a control signal (usually, also a pulse width modulation signal) according to the duty cycle signal PWM to control the turning on and the turning off of an upper-side transistor and a lower-side transistor of each inverter of the driving-stage circuit.

FIG. 1 is a schematic diagram of a driving-stage circuit of a conventional motor driving circuit. The driving-stage circuit in FIG. 1 can be adapted to a single-phase motor or a three-phase motor. With consideration to a conversion time for turning on or off a transistor from an off or on state, to prevent the upper-side transistor and the lower-side transistor U and X or V and Y from being turned on simultaneously, which may cause a large current damaging the whole circuit, when the signal generation circuit generates pulse width modulation signals to the upper-side transistor and the lower-side transistor U and X or V and Y, the pulse width modulation signals provided to the upper-side transistor and the lower-side transistor U and X will be complementary signals, and the pulse width modulation signals provided to the upper-side transistor and the lower-side transistor V and Y will also be complementary signals. Furthermore, a time segment will be between transition edges of the pulse width modulation signals provided to the upper-side transistor and the lower-side transistor U and X or V and Y. Generally, this time segment between transition edges of the pulse width modulation signals provided to the upper-side transistor and the lower-side transistor is called a dead time.

FIG. 2A and FIG. 2B show waveforms of an upper-side transistor U and a lower-side transistor X of one inverter in the driving-stage circuit in FIG. 1 when a motor is driven. In FIG. 2A and FIG. 2B, the pulse width modulation signals u and x are provided respectively to the upper-side transistor U and the lower-side transistor X.

As shown in FIG. 2A and FIG. 2B, the upper edges of the pulse width modulation signals u and x are delayed for a dead time Td, such that the upper-side transistor U and the lower-side transistor X can be turned on in turns. When the motor is driven and a current flows from a node UO to a coil, the voltage VUO at the node UO will be shown as FIG. 2A, and when the motor is driven and a current flows from the coil to the node UO, the voltage VUO at the node UO will be shown as FIG. 2B. It should be noted that, in FIG. 2A, “Vd” is a turn-on voltage of the body diode of the lower-side transistor X, and in FIG. 2B, “Vd” is a turn-on voltage of the body diode of the lower-side transistor U. In addition, in FIG. 2A and FIG. 2B, “VDD” is a power supply of the inverters.

It is assumed that the duty cycle signal PWM generated by the system control circuit is T and the on-time of the duty cycle signal PWM is Ton. According to the voltage VUO at the node UO in FIG. 2A, when the motor is driven and a current flows from the node UO to the coil, the equivalent duty cycle of the driving-stage circuit is (Ton−Td)/T. In addition, according to the voltage VUO at the node UO in FIG. 2B, when the motor is driven and a current flows from the coil to the node UO, the equivalent duty cycle of the driving-stage circuit is (Ton+Td)/T.

In FIG. 1, when a current flows from the node UO to the coil and then flows to the node VO through the coil, if the duty cycle of the node UO is D1% and the duty cycle of the node VO is D2%, the coil current is generated according to an ideal duty cycle (D1−D2)%. In this case, if an equivalent duty cycle of the dead time Td is TD%, when the motor is driven, the equivalent duty cycle of the driving-stage circuit generating the coil current will be (D1%−Td%)−(D2%+Td%), which is [(D1−D2)−2Td]%.

Accordingly, even though delaying the transition edges of the pulse width modulation signals provided to the upper-side transistor and the lower-side transistor prevent the upper-side transistor and the lower-side transistor from being turned on simultaneously, there will be a difference between the equivalent duty cycle of the driving-stage circuit and the ideal duty cycle of the driving-stage circuit due to the dead time, which makes a distortion occur in the waveform of the driving current.

### SUMMARY OF THE DISCLOSURE

To prevent a lower-side transistor and an upper-side transistor of a driving-stage circuit from being simultaneously turned and to prevent a distortion of the waveform of a driving current, the present disclosure provides a motor driving circuit. The motor driving circuit helps to prevent the equivalent duty cycle of a driving-stage circuit from being shortened due to the dead time.

In one aspect, the motor driving circuit provided by the present disclosure includes a driving-stage circuit, a system control circuit, a signal generation circuit and a plurality of zero-crossing detectors. The driving-stage circuit includes a plurality of inverters connected in parallel, and each inverter includes an upper-side transistor and a lower-side transistor. The system control circuit provides a duty cycle signal. The signal generation circuit is connected between the system control circuit and the driving-stage circuit. The signal generation circuit generates a plurality of pulse width modulation signals according to the duty cycle signal to control the turning on and the turning off of the upper-side transistor and the lower-side transistor of each inverter such that the driving current is provided to drive the motor. The zero-crossing detectors are connected between the driving-stage circuit and the signal generation circuit. The zero-crossing detectors detect a current flowing through a node between the upper-side transistor and the lower-side transistor of each inverter, and accordingly generates a current sensing signal. The signal generation circuit adjusts the width modulation signals according to the current sensing signals, such that an equivalent duty cycle of the driving-stage circuit is not related to a dead time of the motor driving circuit, and a distortion of the waveform of the driving current is prevented.

In one embodiment of the motor driving circuit provided by the present disclosure, when the current sensing signal generated by one of the zero-crossing detectors indicates that the current flowing through the node between the upper-side transistor and the lower-side transistor flows outward, the signal generation circuit makes the upper edge of the pulse width modulation signal provided to the upper-side transistor occur one time segment early and makes the lower edge of the pulse width modulation signal provided to the lower-side transistor occur one time segment early. On the other hand, when the current sensing signal generated by one of the zero-crossing detectors indicates that the current flowing through the node between the upper-side transistor and the lower-side transistor flows inward, the signal generation circuit makes the lower edge of the pulse width modulation signal provided to the upper-side transistor occur one time segment early and makes the upper edge of the pulse width modulation signal provided to the lower-side transistor occur one time segment early.

Therefore, in the motor driving circuit provided by the present disclosure, the signal generation circuit adjusts and generates pulse width modulation signals according to current sensing signals, such that the equivalent duty cycle of the driving stage circuit will not be shortened due to the dead time and the distortion of the waveform of the driving current can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1 is a schematic diagram of a driving-stage circuit of a conventional motor driving circuit.

FIG. 2A and FIG. 2B show waveforms of an upper-side transistor U and a lower-side transistor X of one inverter in the driving-stage circuit in FIG. 1 when a motor is driven.

FIG. 3 is a block diagram of a motor driving circuit according to one embodiment of the present disclosure.

FIG. 4A and FIG. 4B show waveforms of an upper-side transistor U and a lower-side transistor X of one inverter in the motor driving circuit in FIG. 3 when a motor is driven.

FIG. 5A and FIG. 5B show how a signal generation circuit in the motor driving circuit in FIG. 3 adjusts the upper edge and the lower edge of a pulse width modulation signal according to the current sensing signal.

FIG. 6 is a waveform diagram showing the operation of a motor driving circuit according to one embodiment of the present disclosure.

FIG. 7A is a simulation result of a current IUO and a current sensing signal Iu when a conventional motor driving circuit is operated.

FIG. 7B is a simulation result of a current IUO and a current sensing signal Iu when the motor driving circuit according to one embodiment of the present disclosure is operated.

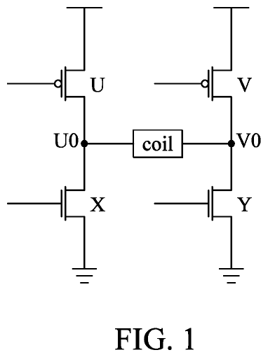

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

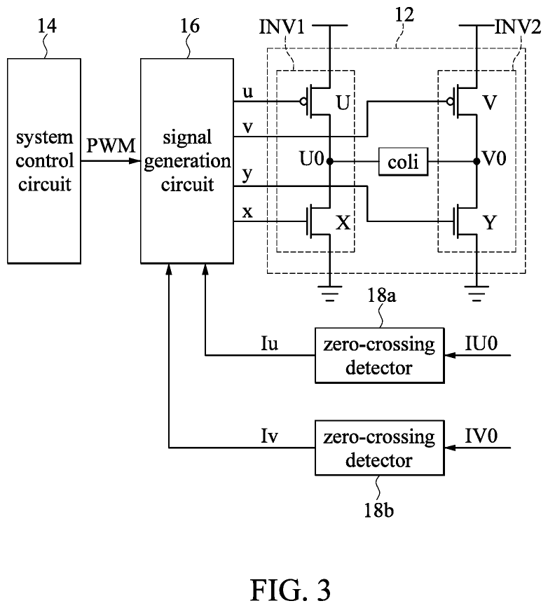

FIG. 3 is a block diagram of a motor driving circuit according to one embodiment of the present disclosure.

As shown in FIG. 3, the motor driving circuit includes a driving-stage circuit 12, a system control circuit 14, a signal generation circuit 16 and a plurality of zero-crossing detectors 18a and 18b. The driving-stage circuit 12 includes two inverters INV1 and INV2 connected in parallel. The inverter INV1 has an upper-side transistor U and a lower-side transistor X, and the inverter INV2 has an upper-side transistor V and a lower-side transistor Y. The system control circuit 14 is configured to provide duty cycle signals PWM. The signal generation circuit 16 is connected between the system control circuit 14 and the driving-stage circuit 12. The signal generation circuit 16 is configured to generate pulse width modulation signals u, x, v and y according to the duty cycle signals PWM to control the turning on and the turning off of the upper-side transistor U and the lower-side transistor X of the inverter INV1 and to control the turning on and the turning off of the upper-side transistor V and the lower-side transistor Y of the inverter INV2, such that a driving current can be provided to a coil for driving the motor.

It should be noted that, the motor driving circuit can be adapted to a single-phase motor or a three-phase motor. Even though only two inverters INV1 and INV2 are shown in the driving-stage circuit 12 in FIG. 3, it is not indicated that the motor driving circuit can only be adapted to a single-phase motor. For ease of understanding, in this embodiment, the motor driven by the motor driving circuit is a single-phase motor, and thus the signal generation circuit 16 generates four pulse width modulation signals u, x, v and y to control the two inverters INV1 and INV2. In other embodiments, the motor driven by the motor driving circuit can be a three-phase motor. In this case, the signal generation circuit 16 generates six pulse width modulation signals to control three inverters.

The working principle of the motor driving circuit in this embodiment is described as follows.

The zero-crossing detectors 18a and 18b are respectively connected between the driving-stage circuit 12 and the signal generation circuit 16. The zero-crossing detectors 18a detects the current IUO flowing through a node between the upper-side transistor U and the lower-side transistor X of the inverter INV1 and accordingly generates a current sensing signal Iu, and the zero-crossing detectors 18b detects the current IVO flowing through a node between the upper-side transistor V and the lower-side transistor Y of the inverter INV2 and accordingly generates a current sensing signal Iv. As for the inverter INV1, when the current IUO detected by the zero-crossing detector 18a is a positive current, it indicates that in the inverter INV1 corresponding to the zero-crossing detector 18a, the current IUO flows out the node UO. Is this case, the zero-crossing detector 18a generates a current sensing signal Iu at low level. On the other hand, when the current IUO detected by the zero-crossing detector 18a is a negative current, it indicates that in the inverter INV1 corresponding to the zero-crossing detector 18a, the current IUO flows into the node UO. Is this case, the zero-crossing detector 18a generates a current sensing signal Iu at high level.

Finally, the signal generation circuit 16 adjusts and generates pulse width modulation signals u and x according to the current sensing signal Iu. Adjusting the pulse width modulation signals u and x according to the current sensing signal Iu is to prevent the equivalent duty cycle of the driving stage circuit 12 from being shortened due to the dead time and to reduce the distortion of the waveform of the driving current.

Details on how the signal generation circuit 16 adjusts the pulse width modulation signals according to the current sensing signal to prevent the equivalent duty cycle of the driving stage circuit 12 from being shortened is described as follows. For ease of understanding, only the operation of the inverter INV1 is described in the following descriptions, and those skilled in the art should be able to accordingly understand the operation of other inverters.

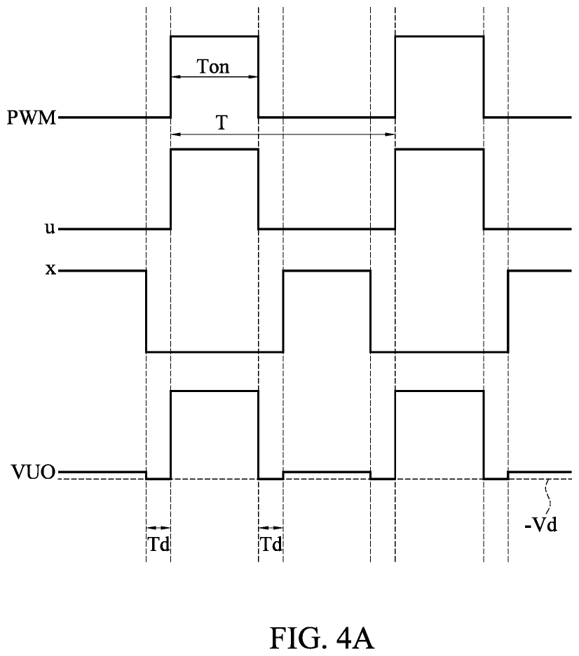

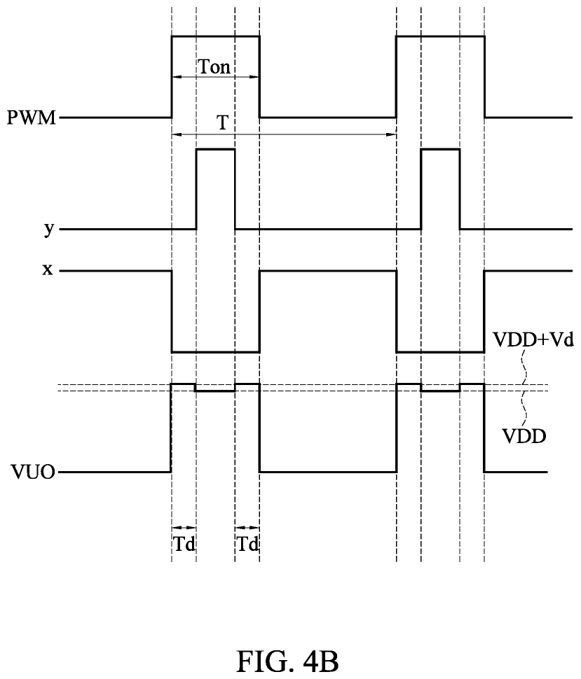

FIG. 4A and FIG. 4B show waveforms of an upper-side transistor U and a lower-side transistor X of one inverter in the motor driving circuit in FIG. 3 when a motor is driven.

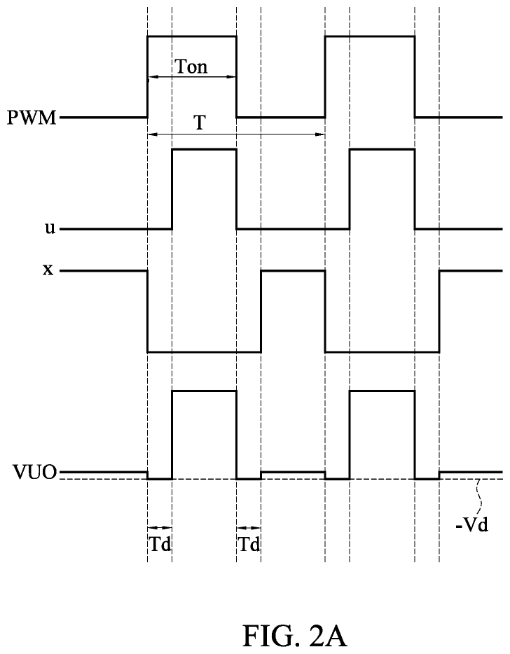

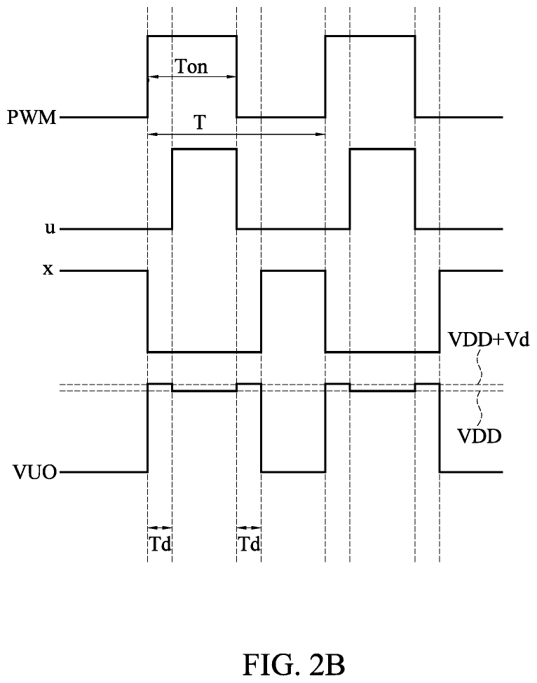

When the zero-crossing detector 18a generates a current sensing signal Iu at low level, it indicates that in the inverter INV1, the current IUO flows out the node UO. In this case, the equivalent duty cycle of the driving-stage circuit in FIG. 2A is (Ton−Td)/T. The equivalent duty cycle of the driving-stage circuit in FIG. 2A is smaller than an ideal duty cycle Ton/T. To improve this defect, as shown in FIG. 4A, the signal generation circuit 16 makes the upper edge of the pulse width modulation signal u provided to the upper-side transistor U occur one time segment early and makes the lower edge of the pulse width modulation signal x provided to the lower-side transistor X occur one time segment early, (compared with FIG. 2A, in FIG. 4A, the upper edge of the pulse width modulation signal u provided to the upper-side transistor U and the lower edge of the pulse width modulation signal x provided to the lower-side transistor X both occur one time segment early.) Due to this adjustment, the time period when the node UO is at high level becomes equal to the on-time Ton of the duty cycle signal PWM, and thus the equivalent duty cycle of the driving-stage circuit 12 is Ton/T, instead of (Ton−Td)/T.

On the other hand, when the zero-crossing detector 18a generates a current sensing signal Iu at high level, it indicates that in the inverter INV1, the current IUO flows into the node UO. In this case, the equivalent duty cycle of the driving-stage circuit in FIG. 2B is (Ton+Td)/T. The equivalent duty cycle of the driving-stage circuit in FIG. 2B is larger than an ideal duty cycle Ton/T. To improve this defect, as shown in FIG. 4B, the signal generation circuit 16 makes the lower edge of the pulse width modulation signal u provided to the upper-side transistor U occur one time segment early and makes the upper edge of the pulse width modulation signal x provided to the lower-side transistor X occur one time segment early, (compared with FIG. 2B, in FIG. 4B, the lower edge of the pulse width modulation signal u provided to the upper-side transistor U and the upper edge of the pulse width modulation signal x provided to the lower-side transistor X both occur one time segment early.) Due to this adjustment, the time period when the node UO is at high level becomes equal to the on-time Ton of the duty cycle signal PWM, and thus the equivalent duty cycle of the driving-stage circuit 12 is Ton/T, instead of (Ton+Td)/T.

For the motor driving circuit in this embodiment, due to the above adjustments of pulse width modulation signals u and x, the equivalent duty cycle of the driving-stage circuit 12 is not related to the dead time of the motor driving circuit. Therefore, the equivalent duty cycle of the driving-stage circuit 12 will not be shortened due to the dead time of the motor driving circuit.

As described, when the zero-crossing detector 18a generates a current sensing signal Iu at low level, the upper edge of the pulse width modulation signal u provided to the upper-side transistor U occurs on time segment early and the lower edge of the pulse width modulation signal x provided to the lower-side transistor X also occurs one time segment early. It is worth mentioning that, the time segment should be equal to the dead time Td of the motor driving circuit. Also, as described, when the zero-crossing detector 18a generates a current sensing signal Iu at high level, the lower edge of the pulse width modulation signal u provided to the upper-side transistor U occurs one time segment early and the upper edge of the pulse width modulation signal x provided to the lower-side transistor X also occurs one time segment early. It is also worth mentioning that, the time segment should be equal to the dead time Td of the motor driving circuit. In this manner, the equivalent duty cycle of the driving-stage circuit 12 is no longer affected by the dead time Td of the motor driving circuit.

Details on how the signal generation circuit 16 adjusts the upper edge and the lower edge of the pulse width modulation signals according to the current sensing signal is described as follows.

In this embodiment, the pulse width modulation signals provided the inverters are generated by the signal generation circuit 16 according to a duty cycle signal PWM provided by the system control circuit 14 and a preset triangular wave.

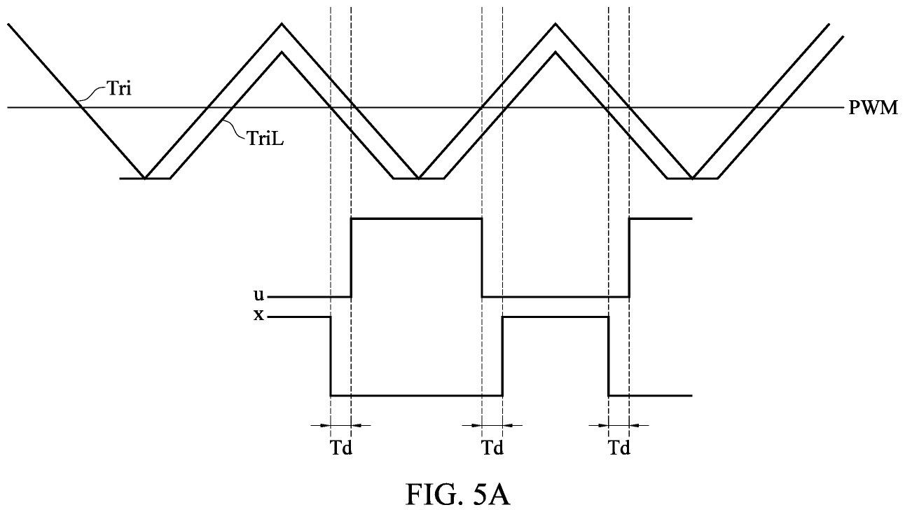

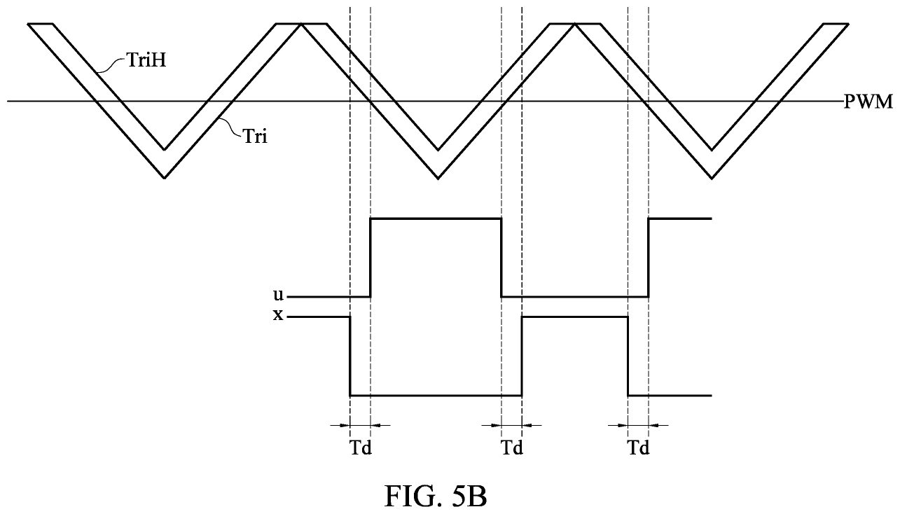

As shown in FIG. 5A, when the current sensing signal Iu generated by the zero-crossing detector 18a indicates that in the inverter INV1, the current IUO flows out the node UO, the signal generation circuit 16 adjusts the preset triangular wave Tri by lowering the preset triangular wave Tri by a preset level to generate an adjusted triangular wave TriL to make the upper edge of the pulse width modulation signal u provided to the upper-side transistor U occur one time segment early and to make the lower edge of the pulse width modulation signal x provided to the lower-side transistor X occur one time segment early. In FIG. 5A, the pulse width modulation signal u generated according to the duty cycle signal PWM and the preset triangular wave Tri is the pulse width modulation signal u in FIG. 4A, and the pulse width modulation signal x generated according to the duty cycle signal PWM and the adjusted triangular wave TriL is the pulse width modulation signal x in FIG. 4A. In this manner, the upper edge of the pulse width modulation signal u of the upper-side transistor U in the inverter INV1 and the lower edge of the pulse width modulation signal x of the lower-side transistor X in the inverter INV1 will both occur one time segment early, such that the equivalent duty cycle of the driving-stage circuit 12 will be Ton/T, instead of (Ton−Td)/T.

In addition, as shown in FIG. 5B, when the current sensing signal Iu generated by the zero-crossing detector 18a indicates that in the inverter INV1, the current IUO flows into the node UO, the signal generation circuit 16 adjusts the preset triangular wave Tri by raising the preset triangular wave Tri by a preset level to generate an adjusted triangular wave TriH to make the lower edge of the pulse width modulation signal u provided to the upper-side transistor U occur one time segment early and to make the upper edge of the pulse width modulation signal x provided to the lower-side transistor X occur one time segment early. In FIG. 5B, the pulse width modulation signal x generated according to the duty cycle signal PWM and the preset triangular wave Tri is the pulse width modulation signal x in FIG. 4B, and the pulse width modulation signal u generated according to the duty cycle signal PWM and the adjusted triangular wave TriH is the pulse width modulation signal u in FIG. 4B. In this manner, the lower edge of the pulse width modulation signal u of the upper-side transistor U in the inverter INV1 and the upper edge of the pulse width modulation signal x of the lower-side transistor X in the inverter INV1 will both occur one time segment early, such that the equivalent duty cycle of the driving-stage circuit 12 will be Ton/T, instead of (Ton+Td)/T.

It should be noted that, in the above described adjustment of the preset triangular wave, the preset level should be relevant to the dead time Td of the motor driving circuit, such that the equivalent duty cycle of the driving-stage circuit 12 can be unaffected by the dead time Td of the motor driving circuit.

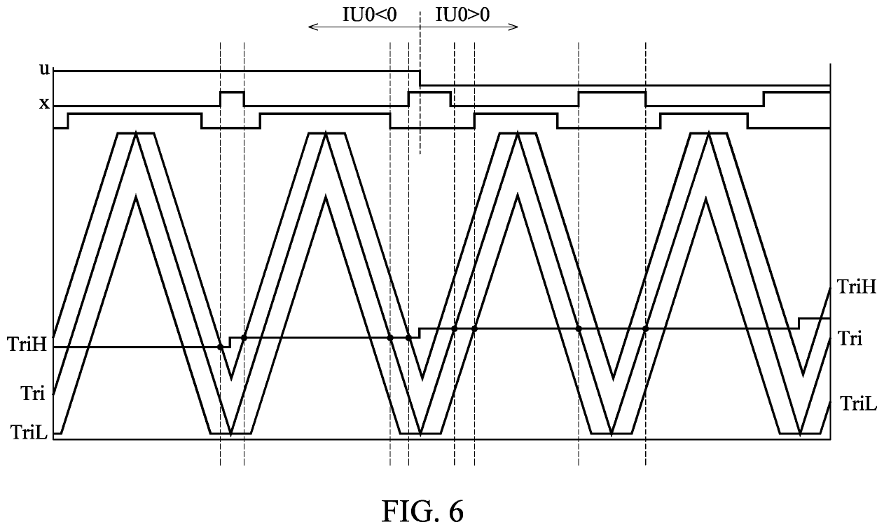

In conclusion, the operation of the motor driving circuit in this embodiment can be referred to in FIG. 6. FIG. 6 is a waveform diagram showing the operation of a motor driving circuit according to one embodiment of the present disclosure. As shown in FIG. 6, when the current IUO detected by the zero-crossing detector 18a is a positive current, the signal generation circuit 16 adjusts the preset triangular wave Tri by lowering the preset triangular wave Tri by a preset level to generate an adjusted triangular wave TriL. Then, the signal generation circuit 16 generates pulse width modulation signals u and x provided respectively to the upper-side transistor U and the lower-side transistor X of the inverter INV1 according to the duty cycle signal PWM, the preset triangular wave Tri and the adjusted triangular wave TriL. On the other hand, when the current IUO detected by the zero-crossing detector 18a is a negative current, the signal generation circuit 16 adjusts the preset triangular wave Tri by raising the preset triangular wave Tri by a preset level to generate an adjusted triangular wave TriH. Then, the signal generation circuit 16 generates pulse width modulation signals u and x provided respectively to the upper-side transistor U and the lower-side transistor X of the inverter INV1 according to the duty cycle signal PWM, the preset triangular wave Tri and the adjusted triangular wave TriH.

From the above descriptions, in the present disclosure, the signal generation circuit adjusts pulse width modulation signals provided to the driving-stage circuit according to current sensing signals, to prevent the equivalent duty cycle of the driving-stage circuit 12 from being shortened due to the dead time. As a result, a distortion of the waveform of the driving current can prevented.

In short, in the present disclosure, the equivalent duty cycle of the driving-stage circuit 12 will not be shortened due to the dead time, and thus the waveform of the driving current (e.g., the current IUO) will not have a distortion.

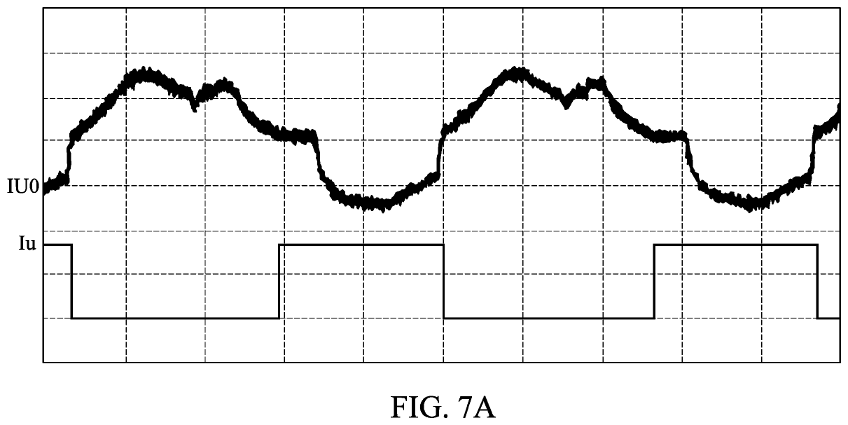

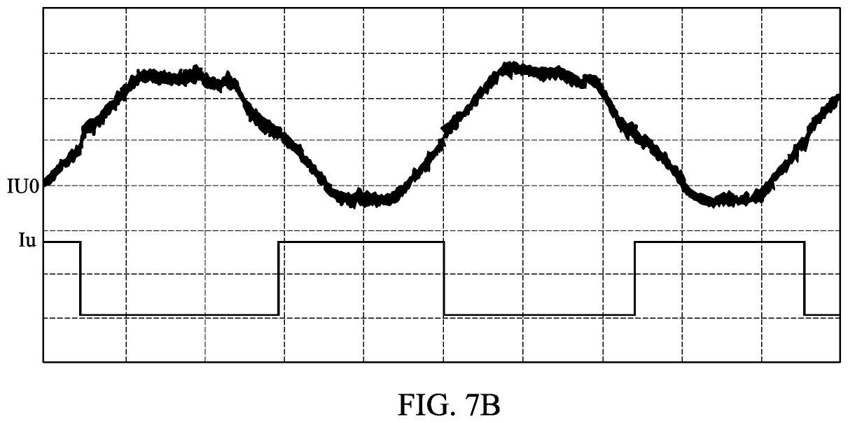

FIG. 7A is a simulation result of a current IUO and a current sensing signal Iu when a conventional motor driving circuit is operated, and FIG. 7B is a simulation result of a current IUO and a current sensing signal Iu when the motor driving circuit according to one embodiment of the present disclosure is operated. As shown in FIG. 7B, in the present disclosure, the pulse width modulation signals provided to the driving-stage circuit will be adjusted according to current sensing signals, and thus when the motor driving circuit is operated, the waveform of the current IUO will not have a distortion at its zero-crossing point (i.e., the time point when the current sensing signal turns from a positive value to a negative value or from a negative value to a positive value). On the contrary, as shown in FIG. 7A, in a conventional motor driving circuit, the pulse width modulation signals provided to a driving-stage circuit will not be adjusted according to current sensing signals, and thus when the motor driving circuit is operated, the waveform of the current IUO will have a distortion at its zero-crossing point (i.e., the time point when the current sensing signal turns from a positive value to a negative value or from a negative value to a positive value).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A motor driving circuit, providing a driving current to drive a motor, comprising:
a driving-stage circuit, including a plurality of inverters connected in parallel, wherein each inverter includes an upper-side transistor and a lower-side transistor;
a system control circuit, providing a duty cycle signal;
a signal generation circuit, connected between the system control circuit and the driving-stage circuit, generating a plurality of pulse width modulation signals according to the duty cycle signal to control the turning on and the turning off of the upper-side transistor and the lower-side transistor of each inverter such that the driving current is provided to drive the motor; and
a plurality of zero-crossing detectors, connected between the driving-stage circuit and the signal generation circuit, detecting a current flowing through a node between the upper-side transistor and the lower-side transistor of each inverter and accordingly generating a current sensing signal;
wherein the signal generation circuit adjusts the width modulation signals according to the current sensing signals, such that an equivalent duty cycle of the driving-stage circuit is not related to a dead time of the motor driving circuit and a distortion of the waveform of the driving current is prevented.

2. The motor driving circuit according to claim 1, wherein when the current sensing signal generated by one of the zero-crossing detectors indicates that the current flowing through the node between the upper-side transistor and the lower-side transistor flows outward, the signal generation circuit makes the upper edge of the pulse width modulation signal provided to the upper-side transistor occur one time segment early and makes the lower edge of the pulse width modulation signal provided to the lower-side transistor occur one time segment early, the time segment being equal to the dead time of the motor driving circuit.

3. The motor driving circuit according to claim 1, wherein when the current sensing signal generated by one of the zero-crossing detectors indicates that the current flowing through the node between the upper-side transistor and the lower-side transistor flows inward, the signal generation circuit makes the lower edge of the pulse width modulation signal provided to the upper-side transistor occur one time segment early and makes the upper edge of the pulse width modulation signal provided to the lower-side transistor occur one time segment early, the time segment being equal to the dead time of the motor driving circuit.

4. The motor driving circuit according to claim 1, wherein each pulse width modulation signal is generated according to the duty cycle signal and a preset triangular wave.

5. The motor driving circuit according to claim 4, wherein when the current sensing signal generated by one of the zero-crossing detectors indicates that the current flowing through the node between the upper-side transistor and the lower-side transistor flows outward, the signal generation circuit adjusts the preset triangular wave by lowering the preset triangular wave by a preset level and generates the pulse width modulation signal according to the duty cycle signal and the adjusted preset triangular wave.

6. The motor driving circuit according to claim 4, wherein when the current sensing signal generated by one of the zero-crossing detectors indicates that the current flowing through the node between the upper-side transistor and the lower-side transistor flows inward, the signal generation circuit adjusts the preset triangular wave by raising the preset triangular wave by a preset level and generates the pulse width modulation signal according to the duty cycle signal and the adjusted preset triangular wave.

7. The motor driving circuit according to claim 5, wherein the preset level is related to the dead time of the motor driving circuit.

8. The motor driving circuit according to claim 6, wherein the preset level is related to the dead time of the motor driving circuit.

9. The motor driving circuit according to claim 1, wherein the motor driven by the motor driving circuit is a single-phase motor or a three-phase motor.

10. The motor driving circuit according to claim 8, wherein when the motor driven by the motor driving circuit is a single-phase motor, the signal generation circuit generates four pulse width modulation signals to control two inverters.

11. The motor driving circuit according to claim 8, wherein when the motor driven by the motor driving circuit is a three-phase motor, the signal generation circuit generates six pulse width modulation signals to control three inverters.
